(19) United States
(12) Patent Application Publication
(10) Pub. No.: US 2026/0259351 A1
(43) Pub. Date: Sep. 3, 2026

(54) SEMICONDUCTOR DEVICE AND METHOD OF MANUFACTURING THE SAME

(71) Applicant: SAMSUNG ELECTRONICS CO., LTD., Suwon-si (KR)

(72) Inventor: Seunghoon HAN, Suwon-si (KR)

(73) Assignee: SAMSUNG ELECTRONICS CO., LTD., Suwon-si (KR)

(21) Appl. No.: 19/535,792

(22) Filed: Feb. 10, 2026

(30) Foreign Application Priority Data
Feb. 28, 2025 (KR) 10-2025-0026916

(51) Int. Cl. G02B 1/11; H10W 29/00; H10B 12/00; H10B 43/35

(52) U.S. Cl. CPC G02B 1/11; H10W 29/00; H10B 12/01; H10B 12/30; H10B 43/35

(57) ABSTRACT

A semiconductor device may include: a semiconductor substrate; a first stacked structure on the semiconductor substrate in a first direction, the first stacked structure including first material layers and second material layers that are alternately arranged in the first direction, the first material layers and the second material layers having different refractive indices from each other, and wherein the first stacked structure includes first through holes extending through the first material layers and the second material layers in the first direction; and a first anti-reflective layer on the first stacked structure in the first direction, the first anti-reflective layer including a first anti-reflective material, and wherein the first anti-reflective layer includes first pattern holes respectively in communication with the first through holes of the first stacked structure, wherein a light reflectance of the first anti-reflective layer is 25% or less.

### CROSS-REFERENCE TO RELATED APPLICATION

This application is based on and claims priority under 35 U.S.C. §119 to Korean Patent Application No. 10-2025-0026916, filed on February 28, 2025, in the Korean Intellectual Property Office, the disclosure of which is incorporated by reference herein in its entirety.

### BACKGROUND

### FIield

The disclosure relates to a semiconductor device and a method of manufacturing the same.

### Description of Related Art

Memory devices may be in a form in which three-dimensional (3D) memory cell structures are stacked as a plurality of layers, starting from a vertical NAND (VNAND). To ensure the performance of memory devices, a structure such as, for example, the thickness or physical properties of thin films used in a process of forming such a multi-stack structure, may be measured. Accordingly, methods for internal measurement inspection of increasingly deep 3D memory structures are being explored.

### SUMMARY

Provided are a semiconductor device having a structure that enables non-destructive inspection during a manufacturing process, and a method of manufacturing the semiconductor device.

According to an aspect of the disclosure, a semiconductor device may include: a semiconductor substrate; a first stacked structure on the semiconductor substrate in a first direction, the first stacked structure including at least one first material layer and at least one second material layer that are alternately arranged with respect to each other in the first direction, the at least one first material layer and the at least one second material layer having different refractive indices from each other, and wherein the first stacked structure includes at least one first through hole extending through the at least one first material layer and the at least one second material layer in the first direction; and a first anti-reflective layer on the first stacked structure in the first direction, the first anti-reflective layer including a first anti-reflective material, and wherein the first anti-reflective layer includes at least one first pattern hole respectively in communication with the at least one first through hole of the first stacked structure, wherein a light reflectance of the first anti-reflective layer is 25% or less.

An average refractive index (n_eff_1) of the first anti-reflective layer may satisfy the following condition: 0.9* (n_eff_st1)^{1/2} ≤ n_eff_1 ≤1.2* (n_eff_st1)^{1/2}, wherein n_eff_st1 is an average refractive index of the first stacked structure.

A thickness of the first anti-reflective layer may be 80 nm to 200 nm.

The at least one first through hole of the first stacked structure may include a through hole, and the at least one first pattern hole of the first anti-reflective layer may include a pattern hole in communication with the through hole, and wherein a width of the through hole may be the same as a width of the pattern hole.

The at least one first material layer may include silicon oxide, and wherein the at least one second material layer may include silicon nitride.

A material of the first anti-reflective material may be the same as a material of the at least one first material layer or a material of the at least one second material layer.

The at least one first through hole may include a cylindrical shape or a slit shape.

The at least one first material layer and the at least one second material layer may be stacked alternately at a period of 50 nm or less.

The at least one first through hole may include a plurality of first through holes, and a distance between adjacent ones of the plurality of first through holes may be 200 nm or less.

According to an aspect of the disclosure, the semiconductor device may further include: a second stacked structure on the first anti-reflective layer in the first direction, the second stacked structure including at least one third material layer and at least one fourth material layer that are stacked alternately in the first direction, and wherein the second stacked structure includes at least one second through hole extending through the at least one third material layer and the at least one fourth material layer in the first direction; a second anti-reflective layer between the first anti-reflective layer and the second stacked structure, the second anti-reflective layer including a second anti-reflective material, and wherein the second anti-reflective layer includes at least one second pattern hole; and a third anti-reflective layer on the second stacked structure in the first direction, the third anti-reflective layer including a third anti-reflective material, and wherein the third anti-reflective layer includes at least one third pattern hole.

An average refractive index (n_eff_2) of the second anti-reflective layer may satisfy the following condition: 1.0* (n_eff_st2)^{1/2}≤ n_eff_2 ≤1.2* (n_eff_st2)^{1/2}, wherein n_eff_st2 is an average refractive index of the second stacked structure.

An average refractive index (n_eff_3) of the third anti-reflective layer may satisfy the following condition: 0.9* (n_eff_st2)^{1/2}≤ n_eff_3 ≤1.2* (n_eff_st2)^{1/2}, wherein n_eff_st2 is an average refractive index of the second stacked structure.

A width of the at least one second pattern hole may be equal to or less than a width of the at least one first pattern hole.

A thickness of the second anti-reflective layer may be equal to or less than a thickness of the first anti-reflective layer, and a width of the at least one second pattern hole may be equal to or less than a width of the at least one first pattern hole.

The at least one third material layer may include silicon oxide, and wherein the at least one fourth material layer may include silicon nitride.

A material of the first anti-reflective material may be the same as a material of the second anti-reflective material.

According to an aspect of the disclosure, a semiconductor device may include: a plurality of memory blocks; and an anti-reflective layer on the plurality of memory blocks in a first direction, wherein the anti-reflective layer includes a pattern, the pattern including two or more types of materials having different refractive indices from each other, wherein each of the plurality of memory blocks includes a plurality of memory elements arranged with respect to each other in the first direction, wherein the plurality of memory blocks are arranged with respect to each other in a second direction crossing the first direction, and wherein a light reflectance of the anti-reflective layer is 25% or less.

According to an aspect of the disclosure, a method of manufacturing a semiconductor device may include: forming a stacked material layer by alternately stacking at least one first material layer and at least one second material layer in a first direction, the at least one first material layer and the at least one second material layer having different refractive indices from each other; forming an anti-reflective material layer on the stacked material layer; and forming an anti-reflective layer from the anti-reflective material layer, and a stacked structure from the stacked material layer, by forming a through hole passing through the anti-reflective material layer and the stacked material layer, wherein a reflectance of the anti-reflective layer is 25% or less.

According to an aspect of the disclosure, an average refractive index (n_eff_1) of the anti-reflective layer may satisfy the following condition: 0.9* (n_eff_st1)^{1/2}≤ n_eff_1 ≤1.2* (n_eff_st1)^{1/2}, wherein n_eff_st1 is an average refractive index of the stacked structure.

According to an aspect of the disclosure, the method may further include forming a memory element in the through hole.

Additional aspects of the disclosure will be set forth in part in the description which follows and, in part, will be apparent from the description, or may be learned by practice of the presented example embodiments of the disclosure.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a conceptual view for describing a schematic configuration of a semiconductor device and a non-destructive inspection method for the semiconductor device, according to an embodiment;

FIG. 2 is a perspective view showing a schematic configuration of a semiconductor device according to an embodiment;

FIG. 3 is a cross-sectional view taken along a line A-A of FIG. 2;

FIG. 4 is a graph showing reflectance with respect to a wavelength of incident light according to thicknesses of an anti-reflective layer provided in a semiconductor device according to an embodiment;

FIG. 5 is a cross-sectional view showing a schematic configuration of a semiconductor device according to an embodiment;

FIGS. 6 to 8 are graphs showing reflectance with respect to a wavelength of incident light, according to various thicknesses of a first anti-reflective layer, a second anti-reflective layer, and a third anti-reflective layer provided in a semiconductor device according to an embodiment shown in FIG. 5;

FIG. 9 is a perspective view showing a schematic configuration of a semiconductor device according to an embodiment; and

FIG. 10 is a flowchart of a method of manufacturing a semiconductor device according to an embodiment.

### DETAILED DESCRIPTION

Reference will now be made in detail to non-limiting example embodiments of disclosure, examples of which are illustrated in the accompanying drawings, wherein like reference numerals refer to like elements throughout. In this regard, embodiments of the disclosure may have different forms and embodiments of the disclosure should not be construed as being limited to the descriptions set forth herein. Accordingly, the exampled embodiments are merely described below, by referring to the figures, to explain non-limiting example aspects of the disclosure. As used herein, the term “and/or” includes any and all combinations of one or more of the associated listed items. Expressions such as “at least one of,” when preceding a list of elements, modify the entire list of elements and do not modify the individual elements of the list.

Hereinafter, non-limiting example embodiments of the disclosure will be described in detail with reference to the accompanying drawings. Various modifications may be made from such example embodiments, and the various modifications are included within the spirit and scope of the disclosure. In the drawings, like reference numerals denote like components, and sizes of components in the drawings may be exaggerated for convenience of explanation.

It will be understood that when an element or layer is referred to as being “on,” “connected to,” or “coupled to” another element or layer, it can be directly on, connected to, or coupled to the other element or layer or intervening elements or layers may be present. In contrast, when an element or layer is referred to as being “directly on,” “directly connected to,” or “directly coupled to” another element or layer, there are no intervening elements or layers present.

Although the terms “first,” “second,” etc., may be used herein to describe various components, these terms are used to distinguish one component from other components. These terms do not necessarily require that materials or structures of components are different from one another.

Singular forms may include plural forms unless apparently indicated otherwise contextually. In case that a portion is referred to as “comprising” or “including” a component, the portion may further include another component unless stated otherwise.

The term used herein such as “unit” or “module” indicates a unit for processing at least one function or operation, and may be implemented in hardware, software, or in a combination of hardware and software.

The use of the terms of “the above-described” and similar indicative terms may correspond to both the singular forms and the plural forms.

Operations constituting a method of embodiments of the disclosure may be performed in any suitable order unless it is explicitly stated that they should be performed in only the described order. The use of all exemplary terms (such as “for example,” etc.) is only to describe example aspects, and the scope of the disclosure is not limited by these terms.

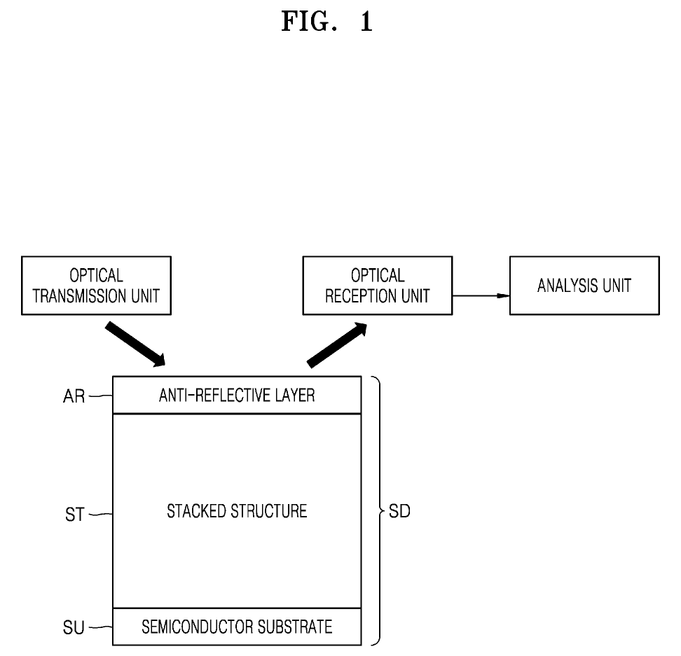

FIG. 1 is a conceptual view for describing a schematic configuration of a semiconductor device and a non-destructive inspection method for the semiconductor device, according to an embodiment.

A semiconductor device SD may include a semiconductor substrate SU, a stacked structure ST, and an anti-reflective layer AR.

The stacked structure ST may include various material layers and patterns used in a process of forming memory elements stacked three-dimensionally. The stacked structure ST may include material layers having, for example, two or more different refractive indices from each other, and the material layers may have fine shape dimensions in a range of several tens of to several hundreds of nm.

The anti-reflective layer AR may be provided to allow an inside of the stacked structure ST to be inspected in a non-destructive optical method (e.g., light irradiated from an optical transmission/reception unit to be incident to the inside of the stacked structure ST). Reflectance of the anti-reflective layer AR may have a small value close to 0. The reflectance of the anti-reflective layer AR may be 25% or less, 20% or less, 10% or less, or 5% or less. The reflectance may mean a reflectance with respect to a wavelength of light provided from the optical transmission/reception unit.

The anti-reflective layer AR may have a three-dimensional (3D) pattern made of materials having two or more different refractive indices. A material, a pattern, or a thickness of the anti-reflective layer AR may be determined for the above-described light reflectance, and an effective refractive index formed by the stacked structure ST may be considered. The thickness of the anti-reflective layer AR may be set based on a value corresponding to 1/4 of a wavelength of light provided from the optical transmission/reception unit. In some embodiments, the thickness may be, but is not limited to, 90% to 110% or 80% to 120% of a 1/4 wavelength. In case that the light provided from the optical transmission/reception unit is in a visible or near-infrared wavelength band, the thickness of the anti-reflective layer AR may be in a range of about 80 nm to about 200 nm.

When a 3D structure inside the stacked structure ST is measured in an optical way, light may be provided into the stacked structure ST and then a phase profile change of light emitted via the inside of the stacked structure ST may be measured. For optical inspection, as is shown, an inspection device including an optical transmission unit (e.g., an optical transmitter), an optical reception unit (e.g., an optical receiver), and an analysis unit (e.g., an analyzer) may be used. Light provided from the optical transmission unit may be incident to the stacked structure ST and may be emitted via a 3D internal structure of the stacked structure ST and received by the optical reception unit. The analysis unit may analyze the internal structure of the stacked structure ST by analyzing a phase delay of the light received by the optical reception unit.

The light provided by the optical transmission unit may be light in the visible or near-infrared wavelength band. The wavelength of light to be used may be appropriately selected based on the reflectance of the anti-reflective layer AR.

In such optical inspection, the stacked structure ST including a plurality of materials having a refractive index over 1 may provide Fabry-Perot resonance conditions for light for measurement. Such resonance may degrade a resolution of a phase image for light passing through the stacked structure ST, and reduce a signal-to-noise ratio (SNR) of a detected signal.

The anti-reflective layer AR included in the semiconductor device SD according to an embodiment may omit one reflection surface that provides Fabry-Perot resonance, thereby improving the accuracy of 3D structure measurement.

While it is shown in FIG. 1 that one anti-reflective layer AR is provided on the stacked structure ST, this is merely an example, and the anti-reflective layer AR may also be arranged inside the stacked structure ST and the number of anti-reflective layers AR may be changed variously. The stacked structure ST may include a structure having a high aspect ratio, and for efficient measurement, for example, a process of further forming a stacked structure and an anti-reflective layer after end of measurement and then optically inspecting the added structure may be repeated.

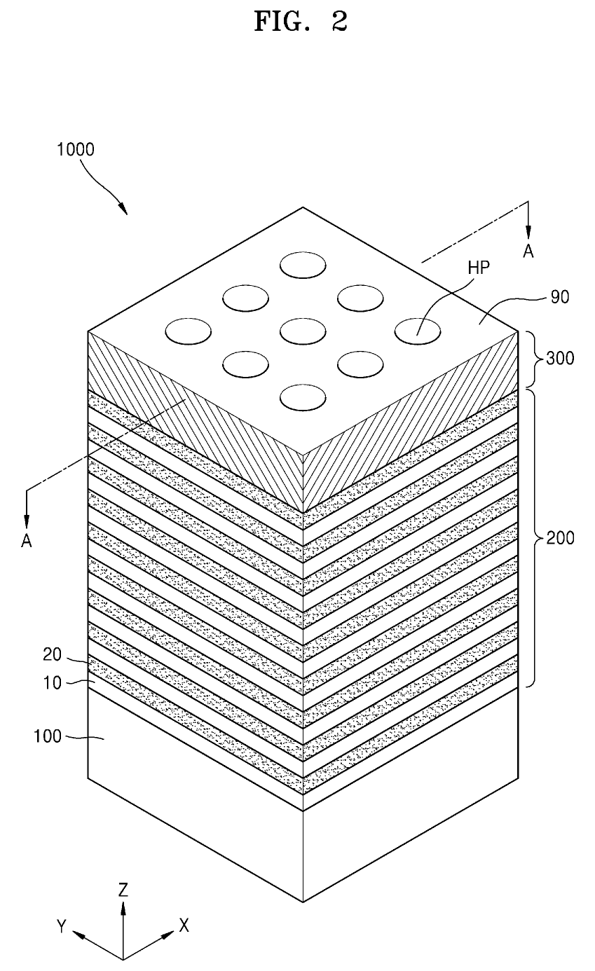

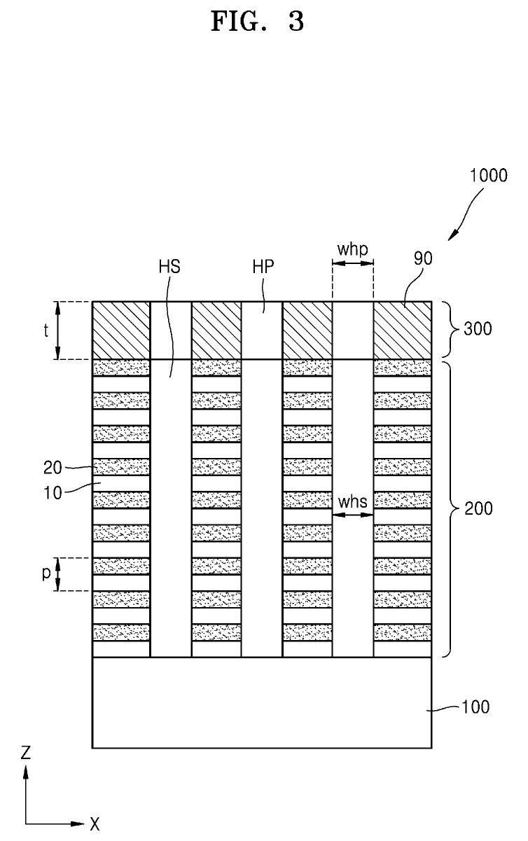

FIG. 2 is a perspective view showing a schematic configuration of a semiconductor device according to an embodiment. FIG. 3 is a cross-sectional view taken along a line A-A of FIG. 2.

A semiconductor device 1000 may include a semiconductor substrate 100 (e.g., the semiconductor substrate SU of FIG. 1), a stacked structure 200 (e.g., the stacked structure ST of FIG. 1) arranged on the semiconductor substrate 100, and an anti-reflective layer 300 (e.g., the anti-reflective layer AR of FIG. 1) arranged on the stacked structure 200.

The semiconductor substrate 100 may include various semiconductor materials. The semiconductor substrate 100 may include a silicon material such as a silicon material doped with a p-type or n-type dopant. The semiconductor substrate 100 may provide a common source region for a semiconductor channel to be formed in a through hole HS in the stacked structure 200.

The stacked structure 200 may be used in a process of forming a plurality of memory elements arranged in a first direction (e.g., a Z direction). The stacked structure 200 may include a first material layer 10 and a second material layer 20 arranged with respect to each other in the first direction (e.g., the Z direction). The first material layer 10 and the second material layer 20 may have different refractive indices from each other. The first material layer 10 and the second material layer 20 may have different etch ratios from each other. The first material layer 10 may include silicon oxide, and the second material layer 20 may include silicon nitride. However, this is merely an example and embodiments of the disclosure are not limited thereto. A plurality of the first material layer 10 and a plurality of the second material layer 20 may be alternately arranged, and a period p in which the first material layer 10 and the second material layer 20 are repeated may be about 50 nm or less. The period p may be an arrangement period of memory elements to be formed repeatedly in the first direction. The period p may be appropriately determined for an integration degree to be implemented.

The stacked structure 200 may include the through hole HS passing through the first material layer 10 and the second material layer 20. The through hole HS may have a cylindrical shape as is shown, but is not limited thereto. In case that the through hole HS has the cylindrical shape, a width of the through hole HS may be a diameter of the through hole HS. The through hole HS may include air with a refractive index of 1. Although nine through holes HS are shown, this is merely an example and the number of through holes HS may be changed variously. Inside the through hole HS, material layers for memory elements may be formed later. In each through hole HS, a memory block to be manufactured may be defined. One memory block may include a plurality of memory elements arranged in the first direction (e.g., the Z direction), and a plurality of memory blocks may be arranged in a second direction (e.g. an X direction) and a third direction (e.g., a Y direction) that are perpendicular to the first direction.

According to an embodiment, an arrangement period of the through holes HS may be 200 nm or less. For example, a distance between edges or centers of adjacent ones of the through holes HS may be 200 nm or less. However, embodiments of the disclosure are not limited thereto, and various arrangement periods may be provided.

The anti-reflective layer 300 may include an anti-reflective material 90 and have a thickness t. The anti-reflective material 90 may include a material included in the first material layer 10 or the second material layer 20. The anti-reflective material 90 may include, for example, silicon nitride or silicon oxide. However, this is merely an example and embodiments of the disclosure are not limited thereto.

A plurality of pattern holes HP may be formed in the anti-reflective layer 300. Each pattern hole HP may have the same shape (e.g., a cylindrical as the through hole HS and may have a cylindrical shape. Each pattern hole HP may be connected to (e.g., in communication with) a respective through hole HS formed in the stacked structure 200. In FIG. 3, a width whp of the pattern hole HP and a width whs of the through hole HS are illustrated as being equal to each other, but this illustration is for convenience and embodiments of the disclosure are not limited thereto. The width whp of the pattern hole HP may be greater than or less than the width whs of the through hole HS. While the width whs of the through hole HS is shown as being constant, it may not be constant and may differ with a depth position. In some embodiments, the width whs may narrow toward the semiconductor substrate 100, which is a phenomenon generally occurring in an etching process of forming the through hole HS. In this case, the width of the pattern hole HP may be formed to correspond to (e.g., be equal to) an average width of the through hole HS.

Light reflectance of the anti-reflective layer 300 may be 25% or less, 20% or less, 10% or less, or 5% or less.

An average refractive index (n_eff_1) of the anti-reflective layer 300 may satisfy the following condition:

0.9* (n_eff_st1)^{1/2}≤ n_eff_1 ≤1.2* (n_eff_st1)^{1/2},

wherein n_eff_st1 may be an average refractive index of the stacked structure 200.

The average refractive index of the stacked structure 200 may be calculated based on a refractive index of the first material layer 10, a refractive index of the second material layer 20, a refractive index inside the through hole HS, and detailed shapes of the first material layer 10, the second material layer 20, and the through hole HS.

The thickness t of the anti-reflective layer 300 may be at least 80 nm, and equal to or less than 200 nm. Such a thickness may be for a case where a light source used for inspection is visible light or near-infrared light, and may be changed based on a wavelength and a reflectance.

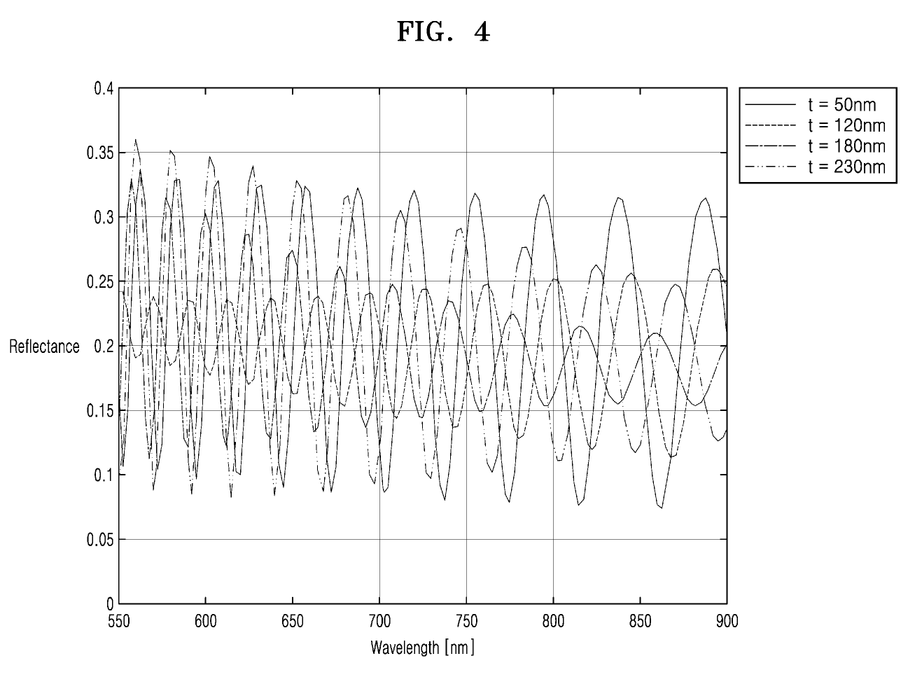

FIG. 4 is a graph showing reflectance with respect to a wavelength of incident light according to thicknesses of an anti-reflective layer provided in a semiconductor device according to an embodiment.

For the thickness t of the anti-reflective layer 300 being 50 nm, 120 nm, 180 nm, and 230 nm, the reflectance of light in a wavelength band of 550 nm to 900 nm is computer-simulated. Referring to the graph, a wavelength band in which a reflectance is 25% or less differs with a thickness, and for example, for a thickness t of 180 nm, a reflectance is 25% or less for light in a wavelength band of 700 nm to 900 nm.

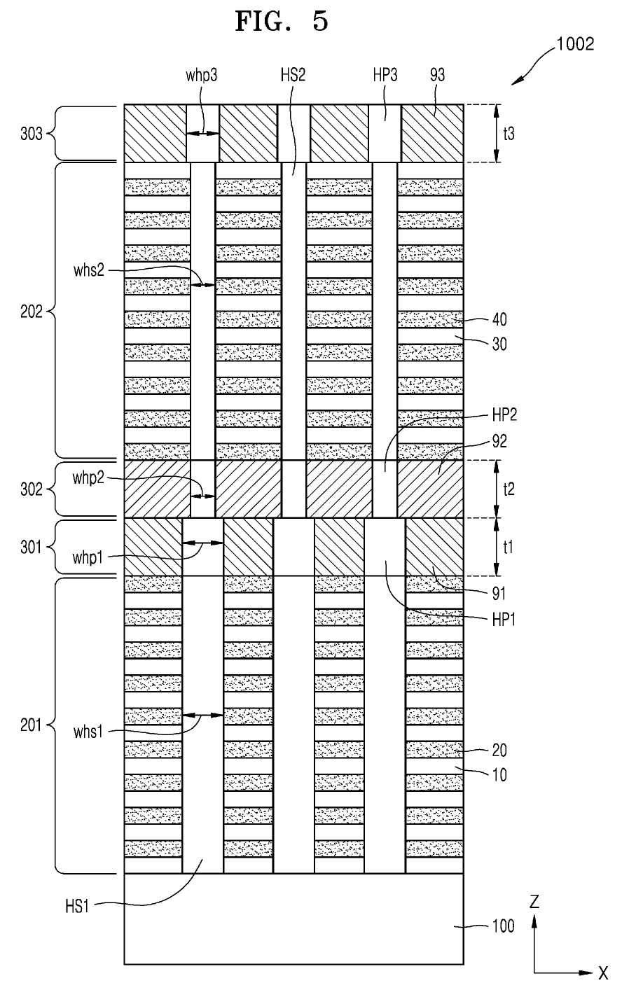

FIG. 5 is a cross-sectional view showing a schematic configuration of a semiconductor device according to an embodiment.

A semiconductor device 1002 according to the embodiment may include the semiconductor substrate 100, and a first stacked structure 201 and a second stacked structure 202 arranged on the semiconductor substrate 100 in the first direction (e.g., the Z direction), and may further include a first anti-reflective layer 301 and a second anti-reflective layer 302 between the first stacked structure 201 and the second stacked structure 202, and a third anti-reflective layer 303 on the second stacked structure 202.

The foregoing description of the stacked structure 200 and the anti-reflective layer 300 of the semiconductor device 1000 may be applied to the first stacked structure 201 and the first anti-reflective layer 301. The foregoing description of the first material layer 10, the second material layer 20, and the through hole HS of the stacked structure 200; the width whs of the through hole HS; the anti-reflective material 90 and the pattern hole HP of the anti-reflective layer 300; and the width whp of the pattern hole HP may be applied to the first material layer 10, the second material layer 20, and a through hole HS1 of the first stacked structure 201; a width whs1 of the through hole HS1; a first anti-reflective material 901 and a pattern hole HP1 of the first anti-reflective layer 301, a width whp1 of the pattern hole HP1; and a thickness t1 and an effective refractive index of the first anti-reflective layer 301.

An average refractive index (n_eff_2) of the second anti-reflective layer 302 may satisfy the following condition:

1.0* (n_eff_st2)^{1/2}≤ n_eff_2 ≤1.2* (n_eff_st2)^{1/2},

wherein n_eff_st2 may be an average refractive index of the second stacked structure 202.

The third anti-reflective layer 303 may be arranged on the second stacked structure 202. The third anti-reflective layer 303 may include a third anti-reflective material 93 to allow light for testing the second stacked structure 202 to be sufficiently incident to the second stacked structure 202, and may have a thickness t3. The third anti-reflective material 93 may be the same as a second anti-reflective material 92 of the second anti-reflective layer 302. In the third anti-reflective layer 303, a plurality of pattern holes HP3 having a width whp3 may be formed.

An average refractive index (n_eff_3) of the third anti-reflective layer 303 may satisfy the following condition:

0.9* (n_eff_st2)^{1/2}≤ n_eff_3 ≤1.2* (n_eff_st2)^{1/2},

where n_eff_st2 may be an average refractive index of the second stacked structure 202.

A width whp2 of a pattern hole HP2 of the second anti-reflective layer 302 may be less than the width whp1 of the pattern hole HP1 of the first anti-reflective layer 301, and the width whp3 of a pattern hole HP3 of the third anti-reflective layer 303 may be greater than a width whs2 of a through hole HS2 of the second stacked structure 202. When the pattern hole HP2, the through hole HS, and the pattern hole HP3 are formed in the same etch process, an etched width may decrease as a depth becomes deeper. However, this is merely an example, and embodiments of the disclosure are not limited to the shown width.

Considering widths formed in this way, the effective refractive index of the first anti-reflective layer 301, the effective refractive index of the second anti-reflective layer 302, and the effective refractive index of the third anti-reflective layer 303 may be slightly different from one another, and the thickness t1 of the first anti-reflective layer 301, the thickness t2 of the second anti-reflective layer 302, and the thickness t3 of the third anti-reflective layer 303 may also be different from one another. In some embodiments, the thickness t2 of the second anti-reflective layer 302 may not be more than the thickness t1 of the first anti-reflective layer 301. A sum of the thicknesses t1 and t2 may be determined based on about a 1/4 wavelength of the incident light, and may be determined to minimize a reflectance in terms of a relationship with the thickness t3.

According to embodiments, the effective refractive indexes and the average refractive indexes described in the disclosure may be calculated with respect to a same wavelength of light. For example, the wavelength may be the wavelength of the incident light, and/or may be a wavelength in a visible or near-infrared wavelength band. However, embodiments of the disclosure are not limited thereto.

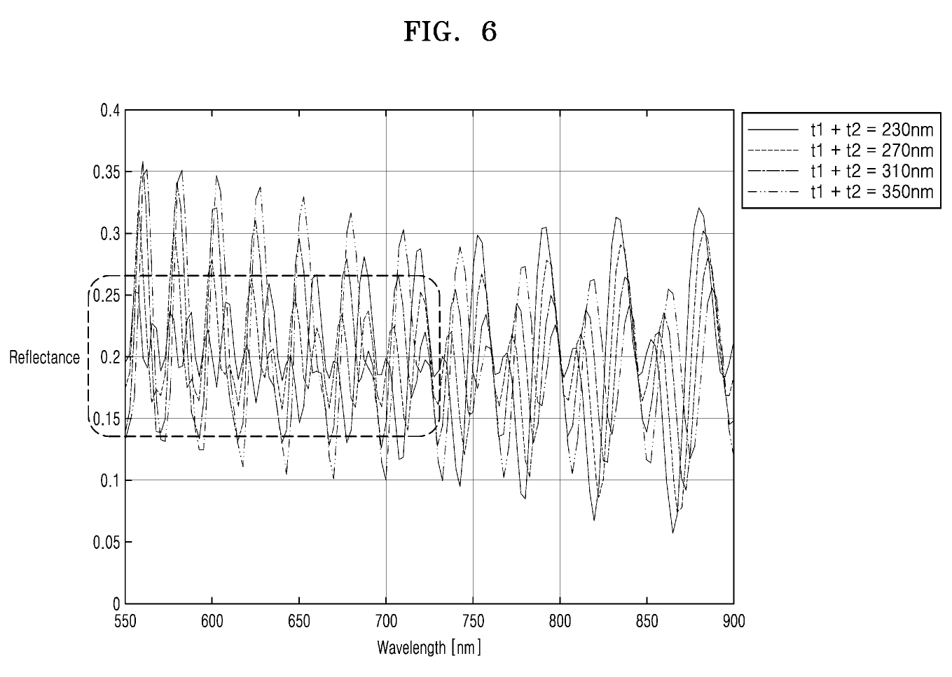

FIGS. 6 to 8 are graphs showing reflectance with respect to a wavelength of incident light according to various thicknesses of a first anti-reflective layer, a second anti-reflective layer, and a third anti-reflective layer provided in a semiconductor device according to an embodiment shown in FIG. 5.

FIG. 6 is a graph in which for a thickness t3 of 125 nm, a reflectance with respect to a wavelength is computer-simulated for a sum of the thickness t1 and the thickness t2 of 230 nm, 270 nm, 310 nm, and 350 nm.

Referring to the graph, in a wavelength band indicated by a dotted box, for the sum of the thickness t1 and the thickness t2 of 230 nm, a reflectance is 30% or less as a whole.

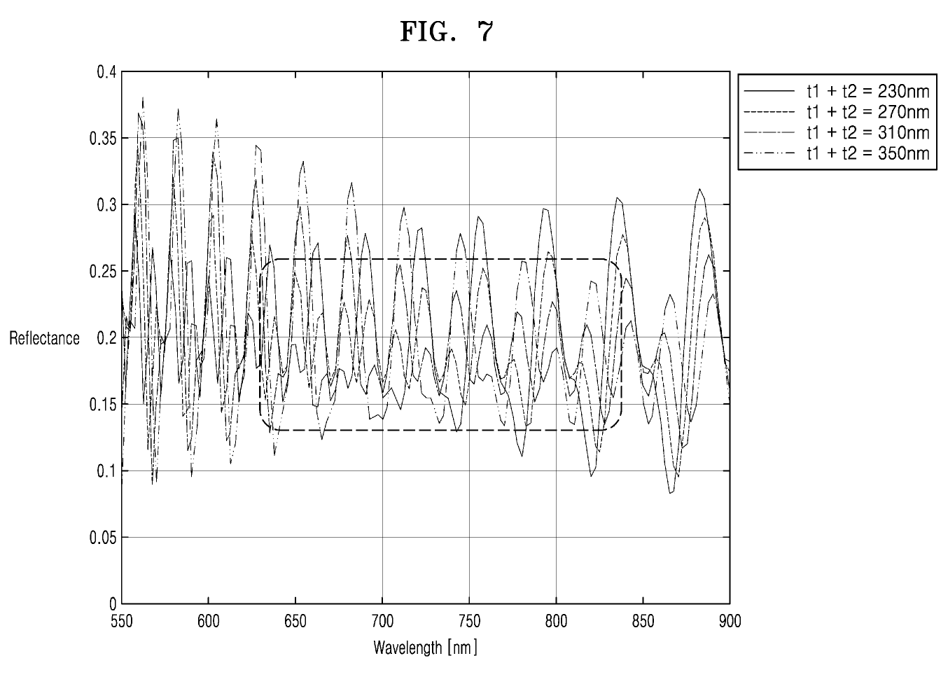

FIG. 7 is a graph in which for a thickness t3 of 150 nm, a reflectance with respect to a wavelength is computer-simulated for the sum of the thickness t1 and the thickness t2 of 230 nm, 270 nm, 310 nm, and 350 nm.

Referring to the graph, in a wavelength band indicated by a dotted box, for the sum of the thickness t1 and the thickness t2 of 270 nm, a reflectance is 30% or less as a whole.

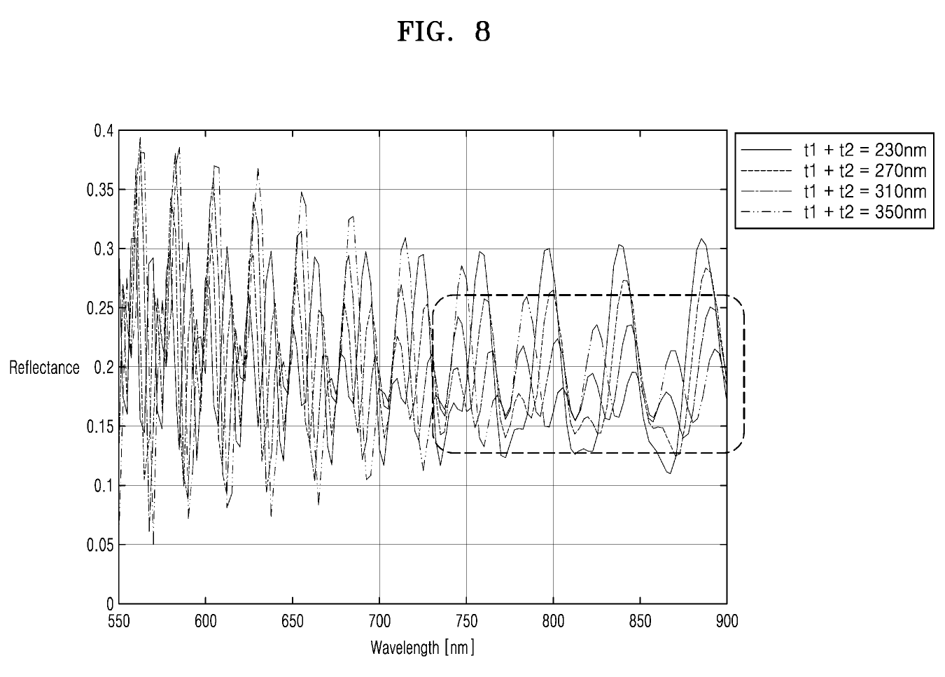

FIG. 8 is a graph in which for a thickness t3 of 175 nm, a reflectance with respect to a wavelength is computer-simulated for the sum of the thickness t1 and the thickness t2 of 230 nm, 270 nm, 310 nm, and 350 nm.

Referring to the graph, in a wavelength band indicated by a dotted box, for the sum of the thickness t1 and the thickness t2 of 310 nm, a reflectance is 30% or less as a whole.

Referring to such computer-simulation results, an appropriate combination of the thicknesses t1, t2, and t3 may be selected based on a wavelength and a reflectance.

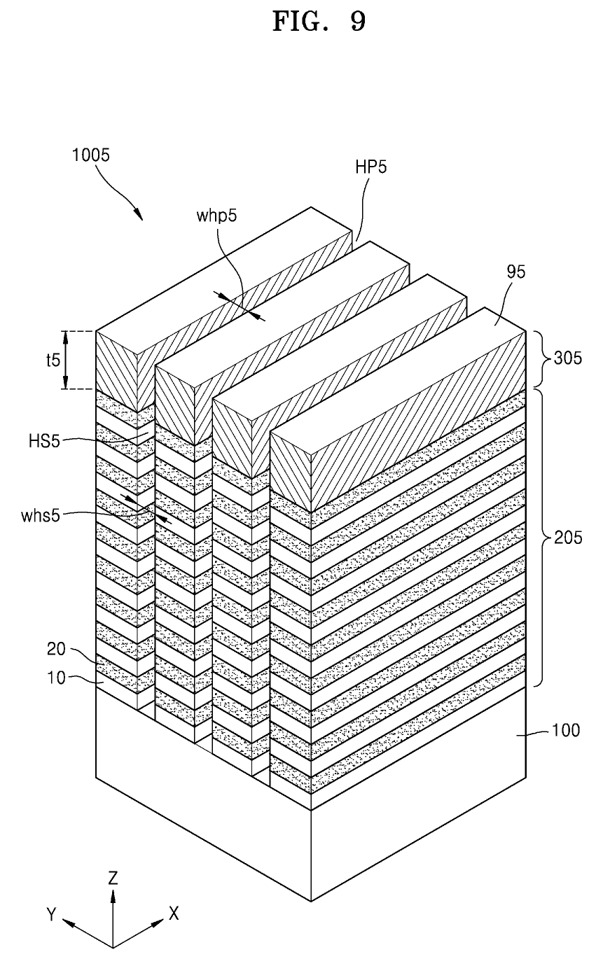

FIG. 9 is a perspective view showing a schematic configuration of a semiconductor device according to an embodiment.

A semiconductor device 1005 may include the semiconductor substrate 100, a stacked structure 205, and an anti-reflective layer 305.

The stacked structure 205 may include a plurality of the first material layer 10 and a plurality of the second material layer 20 that are stacked alternately, and may include at least one through hole HS5 passing through the first material layers 10 and the second material layers 20 and having a width whs5.

The anti-reflective layer 305 may include an anti-reflective material 95 and at least one pattern hole HP5 passing through the anti-reflective material 95 and having a width whp5.

Although the width whs5 of the through hole HS5 is illustrated as being the same as the width whp5 of the pattern hole HP5, this is merely an illustration for convenience, and for example, whp5 may be greater than or less than whs5. Alternately, in case that the width whs5 of the through hole HS5 is not constant according to the depth position of the through hole HS5, the width whp5 of the pattern hole HP5 may be equal to an intermediate width or an average width of the through hole HS5.

The through hole HS5 provided in the stacked structure 205 and the through hole whp5 provided in the anti-reflective layer 305 may be different from through holes of the semiconductor device 1000 of FIG. 2 in that they have a slit shape, (e.g., a thin cuboid shape as is shown), and the other components may be substantially the same as those of the semiconductor device 1000 of FIG. 2.

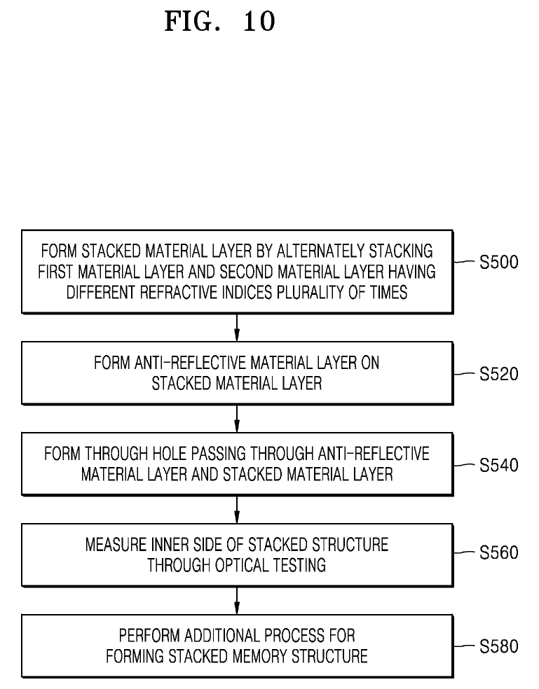

FIG. 10 is a flowchart of a method of manufacturing a semiconductor device according to an embodiment.

A plurality of a first material layer and a plurality of a second material layer having different refractive indices from each other may be alternately stacked several times to form a stacked material layer (operation S500).

The first material layer and the second material layer may be the first material layer 10 and the second material layer 20 described above, and the first material layer and the second material layer may be formed on a semiconductor substrate. The first material layer and the second material layer may have different refractive indices and different etch ratios from each other. Any one of the first material layer and the second material layer may be a sacrificial layer (e.g., may be partially removed in a subsequent process). Any one of the first material layer and the second material layer may include silicon oxide, and the other may include silicon nitride, but embodiments of the disclosure are not limited thereto. To form the first material layer and the second material layer, a deposition method such as atomic layer deposition (ALD)), metal organic atomic layer deposition (MOALD), chemical vapor deposition (CVD), metal organic chemical vapor deposition (MOCVD), physical vapor deposition (PVD), sputtering, etc., may be used. A thickness of each layer, a period in which layers are alternately arranged, and the number of repetition may be determined according to the number of memory cells to be manufactured and an integration degree.

An anti-reflective material layer may be formed on the stacked material layer (operation S520). The anti-reflective material layer may be the same as any one of the first material layer and the second material layer, but embodiments of the disclosure are not limited thereto. The anti-reflective material layer may also be formed using the above-described deposition method.

At least one hole may be formed such as to pass through the anti-reflective material layer and the stacked material layer (operation S540). To form such a hole, photolithography and etching may be used. In case that widths of holes to be formed in the anti-reflective material layer and the stacked material layer are the same as each other, photography and etching may be performed once, and depending on an embodiment, photographing and etching may be performed a plurality of times. A shape of a through hole may be various such as a cylindrical shape, a slit shape, etc., and for example, the stacked structure (e.g., the stacked structure 200 of FIG. 2 or the stacked structure 205 of FIG. 9) and the anti-reflective layer (e.g., the anti-reflective layer 300 of FIG. 2 or the anti-reflective layer 305 of FIG. 9) described above may be manufactured.

An inside of the stacked structure may be measured using optical inspection (operation S560). To measure the inside of the stacked structure, an optical device including an optical transmission unit, an optical reception unit, and an analysis unit as described above with reference to FIG. 1 may be used.

Depending on an embodiment, operations S500 to S560 may be repeated. In the repeated operations, details of the anti-reflective layer and the stacked structure may be changed. In such a process, for example, as shown in FIG. 5, the semiconductor device 1002 including the first stacked structure 201, the second stacked structure 202, the first anti-reflective layer 301, the second anti-reflective layer 302, and the third anti-reflective layer 303 may be manufactured, or a semiconductor device in which additional stacked structure and anti-reflective layers are further stacked may be manufactured.

An additional process for forming a stacked memory structure may be performed (operation S580). Additional material layers for a memory element may be formed in the through hole formed in operation S540, and a part of the first material layer and the second material layer of the stacked structure may be selectively removed. An electrode material may be filled in the removed position. After such a process, a plurality of memory elements may be formed in an extension direction of the through hole, and one memory block including a plurality of memory elements for each through hole may be defined. The manufactured semiconductor device may be, for example, vertical NAND (VNAND) or a vertical stacked dynamic random access memory (VS-DRAM) device.

While non-limiting example embodiments of semiconductor devices and methods of manufacturing the same have been described with reference to the accompanying drawings, it will be understood by those of ordinary skill in the art that various modifications and equivalent other embodiments are possible therefrom, and that the various modifications and equivalent other embodiments are included within the scope of the disclosure. Therefore, the example embodiments should be considered in a descriptive sense rather than a restrictive sense.

The above-described semiconductor devices may have a structure that enables optical non-destructive inspection for a 3D stacked structure in a process of manufacturing a memory device having a three-dimensionally stacked structure.

According to methods of manufacturing a semiconductor device of embodiments of the disclosure, a semiconductor device with a low defect rate may be manufactured.

Descriptions of features or aspects within each embodiment of the disclosure should typically be considered as available for other similar features or aspects in other embodiments of the disclosure. While one or more embodiments have been described with reference to the figures, it will be understood by those of ordinary skill in the art that various changes in form and details may be made therein without departing from the spirit and scope of the disclosure.

What is claimed is:

1. A semiconductor device comprising:
a semiconductor substrate;
a first stacked structure on the semiconductor substrate in a first direction, the first stacked structure comprising at least one first material layer and at least one second material layer that are alternately arranged with respect to each other in the first direction, the at least one first material layer and the at least one second material layer having different refractive indices from each other, and wherein the first stacked structure includes at least one first through hole extending through the at least one first material layer and the at least one second material layer in the first direction; and
a first anti-reflective layer on the first stacked structure in the first direction, the first anti-reflective layer comprising a first anti-reflective material, and wherein the first anti-reflective layer includes at least one first pattern hole respectively in communication with the at least one first through hole of the first stacked structure,
wherein a light reflectance of the first anti-reflective layer is 25% or less.

2. The semiconductor device of claim 1, wherein an average refractive index (n_eff_1) of the first anti-reflective layer satisfies the following condition:
0.9* (n_eff_st1)^{1/2} ≤ n_eff_1 ≤1.2* (n_eff_st1)^{1/2}
wherein n_eff_st1 is an average refractive index of the first stacked structure.

3. The semiconductor device of claim 1, wherein a thickness of the first anti-reflective layer is 80 nm to 200 nm.

4. The semiconductor device of claim 1, wherein the at least one first through hole of the first stacked structure includes a through hole, and the at least one first pattern hole of the first anti-reflective layer includes a pattern hole in communication with the through hole, and
wherein a width of the through hole is the same as a width of the pattern hole.

5. The semiconductor device of claim 1, wherein the at least one first material layer comprises silicon oxide, and
wherein the at least one second material layer comprises silicon nitride.

6. The semiconductor device of claim 1, wherein a material of the first anti-reflective material is the same as a material of the at least one first material layer or a material of the at least one second material layer.

7. The semiconductor device of claim 1, wherein the at least one first through hole comprises a cylindrical shape or a slit shape.

8. The semiconductor device of claim 1, wherein the at least one first material layer and the at least one second material layer are stacked alternately at a period of 50 nm or less.

9. The semiconductor device of claim 1, wherein the at least one first through hole includes a plurality of first through holes, and a distance between adjacent ones of the plurality of first through holes is 200 nm or less.

10. The semiconductor device of claim 1, further comprising:
a second stacked structure on the first anti-reflective layer in the first direction, the second stacked structure comprising at least one third material layer and at least one fourth material layer that are stacked alternately in the first direction, and wherein the second stacked structure includes at least one second through hole extending through the at least one third material layer and the at least one fourth material layer in the first direction;
a second anti-reflective layer between the first anti-reflective layer and the second stacked structure, the second anti-reflective layer comprising a second anti-reflective material, and wherein the second anti-reflective layer includes at least one second pattern hole; and
a third anti-reflective layer on the second stacked structure in the first direction, the third anti-reflective layer comprising a third anti-reflective material, and wherein the third anti-reflective layer includes at least one third pattern hole.

11. The semiconductor device of claim 10, wherein an average refractive index (n_eff_2) of the second anti-reflective layer satisfies the following condition:
1.0* (n_eff_st2)^{1/2}≤ n_eff_2 ≤1.2* (n_eff_st2)^{1/2}
wherein n_eff_st2 is an average refractive index of the second stacked structure.

12. The semiconductor device of claim 10, wherein an average refractive index (n_eff_3) of the third anti-reflective layer satisfies the following condition:
0.9* (n_eff_st2)^{1/2}≤ n_eff_3 ≤1.2* (n_eff_st2)^{1/2}
wherein n_eff_st2 is an average refractive index of the second stacked structure.

13. The semiconductor device of claim 10, wherein a width of the at least one second pattern hole is equal to or less than a width of the at least one first pattern hole.

14. The semiconductor device of claim 10, wherein a thickness of the second anti-reflective layer is equal to or less than a thickness of the first anti-reflective layer, and a width of the at least one second pattern hole is equal to or less than a width of the at least one first pattern hole.

15. The semiconductor device of claim 10, wherein the at least one third material layer comprises silicon oxide, and
wherein the at least one fourth material layer comprises silicon nitride.

16. The semiconductor device of claim 10, wherein a material of the first anti-reflective material is the same as a material of the second anti-reflective material.

17. A semiconductor device comprising:
a plurality of memory blocks; and
an anti-reflective layer on the plurality of memory blocks in a first direction, wherein the anti-reflective layer comprises a pattern, the pattern comprising two or more types of materials having different refractive indices from each other,
wherein each of the plurality of memory blocks comprises a plurality of memory elements arranged with respect to each other in the first direction,
wherein the plurality of memory blocks are arranged with respect to each other in a second direction crossing the first direction, and
wherein a light reflectance of the anti-reflective layer is 25% or less.

18. A method of manufacturing a semiconductor device, the method comprising:
forming a stacked material layer by alternately stacking at least one first material layer and at least one second material layer in a first direction, the at least one first material layer and the at least one second material layer having different refractive indices from each other;
forming an anti-reflective material layer on the stacked material layer; and
forming an anti-reflective layer from the anti-reflective material layer, and a stacked structure from the stacked material layer, by forming a through hole passing through the anti-reflective material layer and the stacked material layer,
wherein a reflectance of the anti-reflective layer is 25% or less.

19. The method of claim 18, wherein an average refractive index (n_eff_1) of the anti-reflective layer satisfies the following condition:
0.9* (n_eff_st1)^{1/2}≤ n_eff_1 ≤1.2* (n_eff_st1)^{1/2}
wherein n_eff_st1 is an average refractive index of the stacked structure.

20. The method of claim 18, further comprising forming a memory element in the through hole.
